(19) United States
(12) Patent Application Publication
(10) Pub. No.: US 2026/0211034 A1
(43) Pub. Date: Jul. 23, 2026

(54) DELAY CELL AND TEST CIRCUITS INCLUDING THE SAME

(71) Applicant: Samsung Electronics Co., Ltd., Suwon-si (KR)

(72) Inventors: Daehyun Kwon, Suwon-si (KR); Hyejung Kwon, Suwon-si (KR); Hyochang Kim, Suwon-si (KR); Jaegeun Song, Suwon-si (KR); Changhoon Song, Suwon-si (KR); Sungwoo Yoon, Suwon-si (KR); Yunsoo Lee, Suwon-si (KR)

(21) Appl. No.: 19/318,887

(22) Filed: Sep. 4, 2025

(30) Foreign Application Priority Data
Jan. 21, 2025 (KR) 10-2025-0008577

(51) Int. Cl. G01R 31/317; H03K 5/00; H03K 5/133

(52) U.S. Cl. CPC G01R 31/31725; H03K 5/133; H03K 2005/00071

(57) ABSTRACT

A test circuit includes a delay line having a plurality of delay cells, each of the plurality of delay cells including an inverter, one end of the inverter being connected to a PMOS capacitor and an NMOS capacitor, a voltage controller, and a measurement circuit. The voltage controller is configured to input a first control voltage to the gate of the PMOS capacitor and the gate of the NMOS capacitor at a first time, and input a second control voltage at a second time after the first time. The measurement circuit is configured to measure a first delay time based on the first control voltage being input, measure a second delay time based on the second control voltage being input, and detect a rising delay time and a falling delay time of the inverter by using a difference between the first delay time and the second delay time.

### CROSS-REFERENCE TO RELATED APPLICATION

This application claims priority under 35 USC 119(a) to Korean Patent Application No. 10-2025-0008577, filed on Jan. 21, 2025, in the Korean Intellectual Property Office, the entire disclosure of which is incorporated herein by reference.

### BACKGROUND

A plurality of semiconductor dies may be manufactured from a single wafer using various semiconductor processes performed on the wafer, and the plurality of semiconductor dies may be separated from each other by a scribing process. The performance of transistors included in the plurality of semiconductor dies may be tested at the wafer level and/or the package level, and a test circuit including a plurality of delay cells may be used.

### SUMMARY

When verifying the characteristics of a transistor using a test circuit including a plurality of delay cells relying on an absolute delay time (propagation delay), it may be difficult to clearly distinguish the characteristics regarding the operating speed of the transistor. Aspects of the present disclosure may address this and other issues in the related art.

In general, aspects of the present disclosure provide a test circuit configured to detect a rising delay time and a falling delay time of a transistor and identify characteristics of an operating speed of a transistor, for example, by using a PMOS capacitor and an NMOS capacitor and measuring a delay time, pulse width, or edge of an output pulse signal while changing a control voltage input to each gate.

According to some implementations of the present disclosure, a test circuit includes a delay line including a plurality of delay cells connected to each other in series, each of the plurality of delay cells including an inverter, a PMOS capacitor, and an NMOS capacitor, a first end of the inverter being connected to the PMOS capacitor and the NMOS capacitor; a voltage controller configured to: input a first control voltage to a gate of the PMOS capacitor and a gate of the NMOS capacitor at a first time, and input a second control voltage to the gate of the PMOS capacitor and the gate of the NMOS capacitor at a second time after the first time, the second control voltage being different from the first control voltage; and a measurement circuit configured to measure a delay time of the inverter using an input voltage input to the delay line and an output voltage output from the delay line, wherein the measurement circuit is configured to: measure a first delay time based on the first control voltage being input to the gate of the PMOS capacitor and the gate of the NMOS capacitor, measure a second delay time based on the second control voltage being input to the gate of the PMOS capacitor and the gate of the NMOS capacitor, and detect a rising delay time and a falling delay time of the inverter by using a difference between the first delay time and the second delay time.

According to some implementations of the present disclosure, a delay cell includes an inverter configured to invert an input pulse signal and including: an input terminal configured to receive the input pulse signal, and an output terminal configured to output the inverted input pulse signal; and a capacitor circuit including a PMOS capacitor and an NMOS capacitor connected to the output terminal of the inverter, wherein the inverter is configured to output a first pulse width of a first output pulse signal based on a first control voltage being input to the capacitor circuit, and configured to output a second pulse width of a second output pulse signal based on a second control voltage different from the first control voltage being input to the capacitor circuit, and wherein the first pulse width and the second pulse width are configured to be compared with each other to detect a rising delay time and a falling delay time of the inverter.

According to some implementations of the present disclosure, a test circuit includes a delay line including a plurality of delay cells connected to each other in series, each of the plurality of delay cells including an inverter, a PMOS capacitor, and an NMOS capacitor, wherein the PMOS capacitor and the NMOS capacitor are connected to an output terminal of the inverter; and a counter including a plurality of shift registers and configured to count a number of pulses of output pulse signals output from the delay line, wherein a number of the plurality of delay cells is N, wherein N is an odd number greater than or equal to 1, and wherein an input terminal of a first delay cell and an output terminal of an Nth delay cell are connected to operate as a feedback loop, and wherein based on a control voltage being input to a gate of the PMOS capacitor and a gate of the NMOS capacitor, the counter is configured to receive the output pulse signals as clock signals and count the number of pulses of the output pulse signals to detect a rising delay time and a falling delay time of the inverter.

### BRIEF DESCRIPTION OF DRAWINGS

Example implementations will be more clearly understood from the following detailed explanations, taken in conjunction with the accompanying drawings.

FIG. 1 is a diagram illustrating a manufacturing process of a semiconductor die according to some implementations.

FIG. 2 is a diagram illustrating a structure of a semiconductor device according to some implementations.

FIG. 3 is a diagram illustrating a structure of a test circuit according to some implementations.

FIGS. 4 to 7 are diagrams illustrating an operation of a test circuit according to some implementations.

FIGS. 8 and 9 are diagrams illustrating a test circuit according to some implementations.

FIG. 10 is a diagram illustrating a delay cell according to some implementations.

FIGS. 11 to 13 illustrate an operation of a test circuit according to some implementations.

FIGS. 14 and 15 are diagrams illustrating an operation of a test circuit according to some implementations.

FIG. 16 is a flowchart illustrating an operation of a test circuit according to some implementations.

### DETAILED DESCRIPTION

Hereinafter, example implementations will be described in detail with reference to the accompanying drawings.

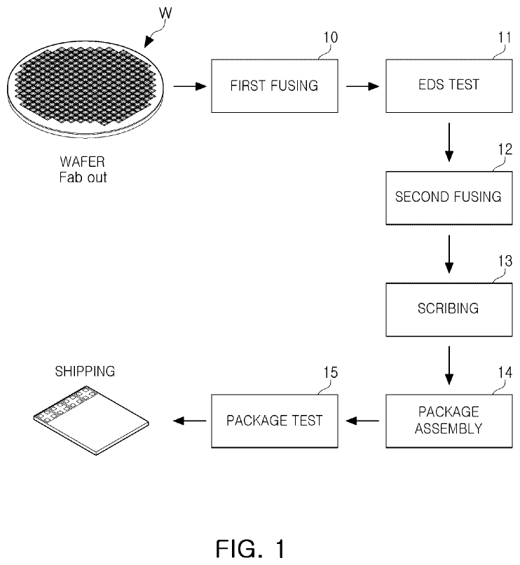

FIG. 1 is a diagram illustrating a manufacturing process of a semiconductor die according to some implementations.

Referring to FIG. 1, in some implementations, a plurality of semiconductor devices are produced by applying semiconductor processes to a wafer W, and the wafer W may be fab-out. The semiconductor devices may be disposed in the form of semiconductor dies on the wafer W. When the wafer W is fab-out, a first fusing 10 may be performed to record data in the first fuse elements. The data recorded in the first fuse elements by the first fusing may include customizing data, repair data, data related to the production/manufacturing history of the semiconductor device, and the like.

After the first fusing 10 is completed, an Electrical Die Sorting (EDS) test 11 may be performed at the wafer level. According to some implementations, the EDS test 11 may include a plurality of tests that are sequentially performed in different environments. After the EDS test 11 is completed, a second fusing 12 may be performed to rewrite the data of the fuse elements. The second fusing 12 may be a procedure performed in consideration of the possibility that the data of the fuse elements may be modified in the EDS test, or the like. After the second fusing 12 is completed, a scribing process 13 for separating the semiconductor dies and a package assembly process 14 may be performed.

After the package assembly process 14, a package test 15 may be performed. For example, the package test 15 may be performed after a semiconductor device has been packaged and mounted on a test board, or the like. The semiconductor device may exchange signals with other semiconductor devices through the test board and, thus, the actual operation of the semiconductor device can be tested through the test board during the package test 15.

In some implementations, the characteristics of the transistors included in the semiconductor die may be verified in the EDS test 11 performed at the wafer level and/or the package test 15 performed at the package level. By comparing the rising delay time and the falling delay time, the characteristics of the transistors may be verified and optimized according to the characteristics of the process. Therefore, the yield of the semiconductor manufacturing process may be improved, and the reliability of the semiconductor die and the semiconductor device manufactured by packaging the same may be improved.

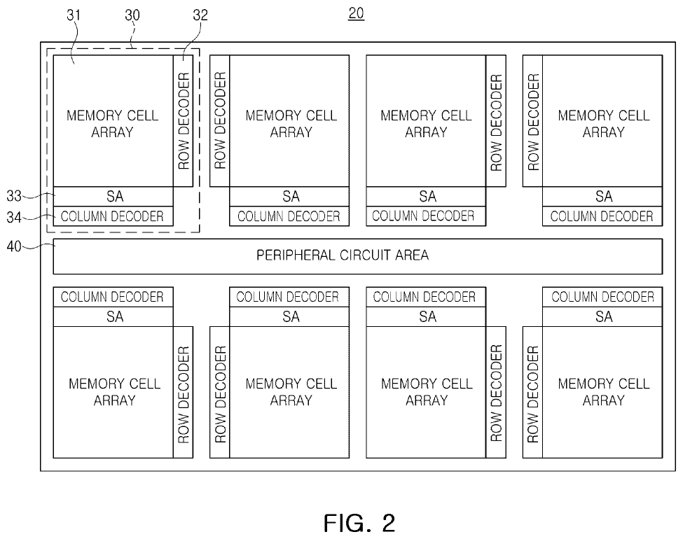

FIG. 2 is a diagram illustrating the structure of a semiconductor device according to some implementations.

Referring to FIG. 2, a semiconductor device 20 according to some implementations may include a cell area a peripheral circuit area 40, and the like. A plurality of banks 30 may be disposed in the cell area. Each of the plurality of banks 30 may include a memory cell array 31, a row decoder 32, a sense amplifier circuit 33, a column decoder 34, and the like. A plurality of memory cells included in the memory cell array 31 may be connected to the row decoder 32, for example, through a plurality of word lines, and may be connected to the sense amplifier circuit 33, for example, through a plurality of bit lines. Meanwhile, in the implementations illustrated in FIG. 2, eight banks 30 are included in the semiconductor device 20, but the number of banks 30 may vary depending on example implementations.

In the peripheral circuit area 40, a logic circuit that controls a plurality of banks 30, an input/output circuit that exchanges signals with other external devices, such as a memory controller, and the like may be disposed. For example, the peripheral circuit area 40 may control program operations, read operations, refresh operations, or the like for each of the plurality of banks 30 based on command signals and address signals received from the memory controller.

In the peripheral circuit area 40, a word line driver, a sense amplifier, a row decoder, a column decoder, and control circuits may be disposed. In the peripheral circuit area 40 according to some implementations, a test circuit that verifies the characteristics of transistors included in the semiconductor die may be included. The test circuit may include a delay line including a plurality of delay cells. A pulse signal may be provided to a delay line, and the pulse width of the pulse signal output through multiple delay cells may be used to detect the rising delay time and falling delay time of the transistors.

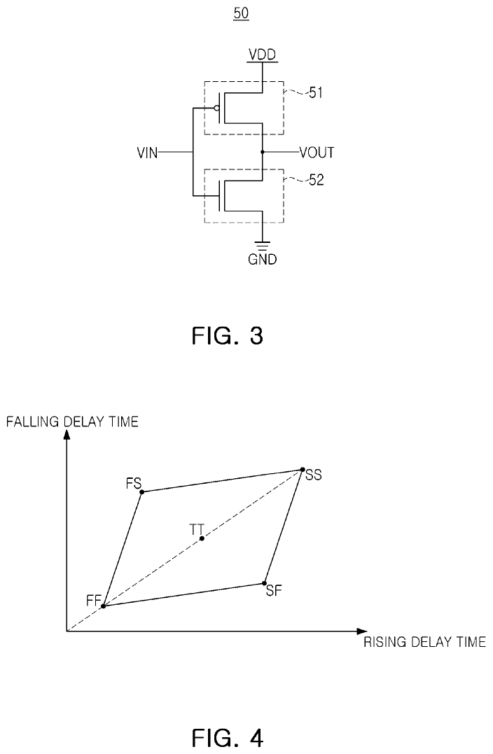

FIG. 3 is a diagram illustrating the structure of a test circuit according to some implementations.

In some implementations, the delay line of the test circuit may include multiple inverters. Each of the multiple inverters may include an input terminal and an output terminal, and may invert an input signal and output the inverted input signal. The inverter 50 may be mainly implemented using a Metal-Oxide-Semiconductor Field-Effect Transistor (MOSFET), and may be implemented with one PMOS transistor 51 and one NMOS transistor 52. In some implementations, the PMOS transistor 51 and the NMOS transistor 52 included in the inverter 50 may be formed in the same process as the multiple transistors in the semiconductor die that is the test target.

In some implementations, the gate of the PMOS transistor 51 in the inverter 50 may be connected to the input terminal of the inverter 50, the source of the PMOS transistor 51 may be connected to the power supply voltage VDD, and the drain of the PMOS transistor 51 may be connected to the output terminal of the inverter 50. When a low voltage is input to the gate of the PMOS transistor 51, the PMOS transistor 51 may be turned on, and the PMOS transistor 51 may transmit the power supply voltage VDD to the output terminal of the inverter 50. When a high voltage is input to the gate of the PMOS transistor 51, the PMOS transistor 51 may be turned off, and the power supply voltage VDD and the output terminal of the inverter 50 may be separated.

In some implementations, the gate of the NMOS transistor 52 may be connected to the input terminal of the inverter 50, the source of the NMOS transistor 52 may be connected to the ground voltage GND, and the drain of the NMOS transistor 52 may be connected to the output terminal of the inverter 50. When a high voltage is input to the gate of the NMOS transistor 52, the NMOS transistor 52 may be turned on, and the NMOS transistor 52 may transmit the ground voltage GND to the output terminal of the inverter 50. When a low voltage is input to the NMOS transistor 52, the NMOS transistor 52 may be turned off, and the ground voltage GND and the output terminal of the inverter 50 may be separated.

In some implementations, the inverter 50 may activate the NMOS transistor 52 to invert the output to low (logic ‘0’) when the input signal is high (logic ‘1’), and activate the PMOS transistor 51 to invert the output to high (logic ‘1’) when the input signal is low (logic ‘0’).

One of the methods for testing the performance of a semiconductor die is to determine the rising delay time and falling delay time of the transistor. For example, the rising delay time of the output voltage VOUT for the input voltage VIN may be affected by the operating speed of the PMOS transistor 51, and the falling delay time may be affected by the operating speed of the NMOS transistor 52. The test circuit according to some implementations may detect the rising delay time and falling delay time, compare the operating speed of the PMOS transistor 51 and the operating speed of the NMOS transistor 52, and optimize the semiconductor die according to the characteristics of the process.

FIGS. 4 to 7 are diagrams illustrating the operation of a test circuit according to some implementations.

FIG. 4 is a result of a process corner simulation and shows a graph illustrating delay times according to respective operation speeds of a plurality of PMOS transistors and a plurality of NMOS transistors included in a test circuit and a test subject. The simulation result graph of FIG. 4 illustrates a case where the respective operation speeds of the plurality of PMOS transistors and the plurality of NMOS transistors are all fast (Fast-Fast, FF), a case where they are all typical (Typical-Typical, TT), and a case where they are all slow (Slow-Slow, SS).

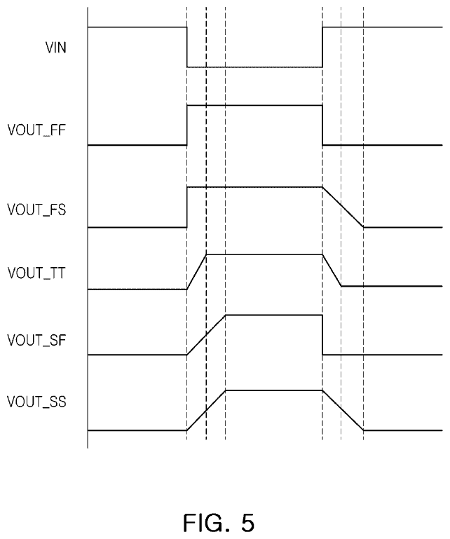

Referring to FIGS. 4 and 5, when the respective operation speeds of the plurality of PMOS transistors and the plurality of NMOS transistors are all fast (FF), both the rising delay time and the falling delay time may be minimum. When an input pulse signal VIN is input to an inverter including a PMOS transistor and an NMOS transistor, an output pulse signal VOUT_FF as illustrated in FIG. 5 may be output. However, when the operating speeds are all fast (FF), a significant amount of current may be consumed.

When the respective operating speeds of the plurality of PMOS transistors and the plurality of NMOS transistors are all slow (SS), both the rising delay time and the falling delay time may be at maximum. When the input pulse signal VIN is input to the inverter, an output pulse signal VOUT_SS may be output as illustrated in FIG. 5. When the respective operating speeds of the plurality of PMOS transistors and the plurality of NMOS transistors are all normal (TT), the rising delay time and the falling delay time may fall between the delay times of the two cases described above (FF, SS). When the input pulse signal VIN is input to the inverter, an output pulse signal VOUT_TT may be output as illustrated in FIG. 5.

In addition, referring to FIG. 4, the graph also illustrates a case where the operating speeds of the plurality of PMOS transistors are fast and the operating speeds of the plurality of NMOS transistors are slow (Fast-Slow, FS), and a case where the operating speeds of the plurality of PMOS transistors are slow and the operating speeds of the plurality of NMOS transistors are fast (Slow-Fast, SF). When the operating speeds of plurality of PMOS transistors are fast and the operating speeds of plurality of NMOS transistors are slow (FS), the rising delay time may be shorter than the falling delay time. When an input pulse signal VIN is input to the inverter, an output pulse signal VOUT_FS may be output as illustrated in FIG. 5. When the operating speeds of plurality of PMOS transistors are slow and the operating speeds of plurality of NMOS transistors are fast (SF), the rising delay time may be longer than the falling delay time. When an input pulse signal VIN is input to the inverter, an output pulse signal VOUT_SF may be output as illustrated in FIG. 5.

Referring to FIG. 5, depending on the characteristics of a transistor, the output pulse signal may or may not be identical to the input pulse signal VIN. The output pulse signals VOUT_FF, VOUT_FS, VOUT_TT, VOUT_SF, and VOUT_SS illustrated in FIG. 5 are signals output after passing through an odd number of inverters. If the input pulse signal VIN is output from a circuit with tens or hundreds of inverters, the rising delay time and the falling delay time may have a relatively significant impact on the output pulse signal.

In some implementations, using an absolute delay time, VOUT_FF and VOUT_SS may be distinguished. For example, the output pulse signal most similar to the input pulse signal may be determined as VOUT_FF, and the output pulse signal most different from the input pulse may be determined as VOUT_SS. However, VOUT_FS, VOUT_TT, and VOUT_SF output from a circuit with tens or hundreds of inverters connected may have similar average delay times, and it may be difficult to determine the characteristics of the transistors.

In some implementations, a PMOS capacitor and an NMOS capacitor may be included in a test circuit for testing the characteristics of the transistors, and the delay characteristics of an output pulse signal with respect to an input pulse signal may be determined while changing the control voltage input to the gate of each of the PMOS capacitor and the NMOS capacitor. For example, a first delay time may be measured by inputting a first control voltage to the respective gates of the PMOS capacitor and the NMOS capacitor, and a second delay time may be measured by inputting a second control voltage to the respective gates of the PMOS capacitor and the NMOS capacitor. The test circuit may detect the rising delay time and the falling delay time by using the difference between the first delay time and the second delay time, and may determine the characteristics of the transistor.

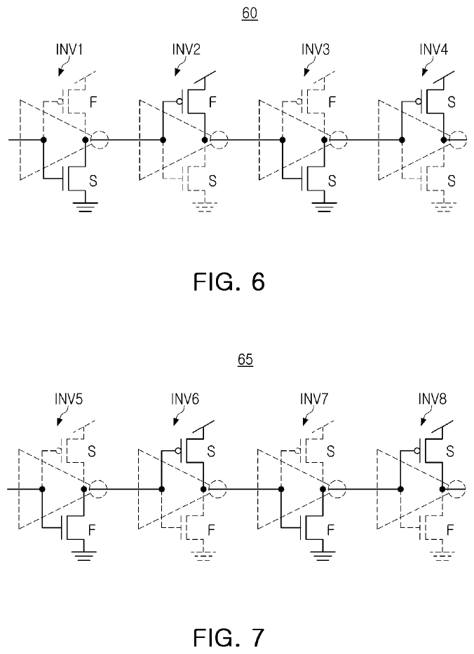

FIG. 6 is a diagram illustrating a first test circuit 60 according to some implementations. The first test circuit 60 may include a plurality of delay cells, and the plurality of respective delay cells may be implemented as inverter INV1 to INV4. Referring to FIG. 6, four delay cells are illustrated, but the present disclosure is not limited thereto, and the test circuit may include more or fewer delay cells.

When a pulse signal having a voltage corresponding to logic ‘1’ is input to the first test circuit 60, the NMOS transistor of the first inverter INV1 may be turned on by the pulse signal. In the second inverter INV2, the PMOS transistor may be turned on by the output pulse signal of the first inverter INV1, and in the third inverter INV3, the NMOS transistor may be turned on by the output pulse signal of the second inverter INV2. Meanwhile, in the fourth inverter INV4, the PMOS transistor may be turned on by the output pulse signal of the third inverter INV3.

Each of the inverters INV1-INV4 may include one PMOS transistor and one NMOS transistor. In some cases, the PMOS transistor is manufactured well, so that the operating speed of the PMOS transistor is relatively fast, and the characteristics of the NMOS transistor are relatively deteriorated due to the manufacturing process of the NMOS transistor, so that the operating speed of the NMOS transistor may be relatively slow. However, this may not mean that the operating speed of the transistor is faster than the operating speed of the NMOS transistor. If the characteristics of the PMOS transistor is relatively good and the characteristics of the NMOS transistor is relatively bad, the falling delay time may be longer than the rising delay time.

FIG. 7 is a diagram illustrating a second test circuit 65 according to some implementations. The second test circuit 65 may include a plurality of delay cells, and the plurality of respective delay cells may be implemented as inverters INV5 to INV8.

When a pulse signal having a voltage corresponding to logic ‘1’ is input to the second test circuit 65, the NMOS transistor of the fifth inverter INV5 may be turned on by the pulse signal. In the sixth inverter INV6, the PMOS transistor may be turned on by the output pulse signal of the fifth inverter INV5, and in the seventh inverter INV7, the NMOS transistor may be turned on by the output pulse signal of the sixth inverter INV6. Meanwhile, in the eighth inverter INV8, the PMOS transistor may be turned on by the output pulse signal of the seventh inverter INV7.

Each of the inverters INV5 to INV8 may include one PMOS transistor and one NMOS transistor, and in some cases, the NMOS transistor is manufactured well so that the operating speed of the NMOS transistor is relatively fast, and the characteristics of the PMOS transistor are relatively deteriorated due to the manufacturing process of the PMOS transistor so that the operating speed of the PMOS transistor is relatively slow. If the characteristics of the NMOS transistor is relatively good and the characteristics of the PMOS transistor is relatively bad, the rising delay time may be longer than the falling delay time.

As described with reference to FIGS. 6 and 7, if the output pulse signal is output from a circuit in which tens or hundreds of inverters are connected, the delay time of the first test circuit 60 and the average delay time of the second test circuit 65 may appear similar. Therefore, it may be difficult to detect the rising delay time and the falling delay time using the absolute delay time to determine the characteristics of the transistor.

A test circuit according to some implementations may measure the pulse width of the output pulse signal by connecting a PMOS capacitor and an NMOS capacitor to the output terminal of the inverter and changing the control voltage input to each of the gates of the PMOS capacitor and the NMOS capacitor. For example, the rising delay time and the falling delay time may be detected by using the difference between a first pulse width measured by inputting a voltage lower than the threshold voltage to the gate of the PMOS capacitor and a second pulse width measured by inputting a voltage higher than the threshold voltage to the gate of the NMOS capacitor. Based on the test results, the characteristics of the transistor's operating speed may be identified and optimized according to the characteristics of the process.

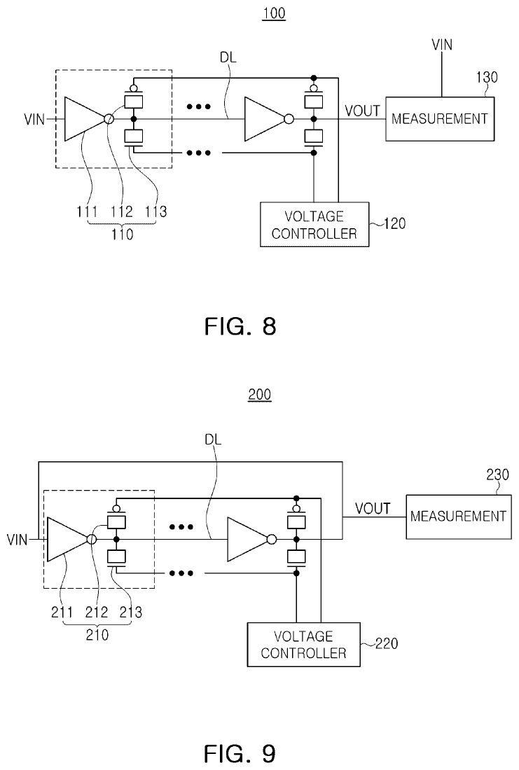

FIGS. 8 and 9 are diagrams illustrating a test circuit according to some implementations.

Referring to FIG. 8, a test circuit 100 according to some implementations may include a delay line DL, a voltage controller 120, and a measurement circuit 130.

The delay line DL may include a plurality of delay cells 110 that are connected to each other in series. Each of the plurality of delay cells 110 may include an inverter 111, a PMOS capacitor 112, and an NMOS capacitor 113. In some implementations, one end of the inverter 111 may be connected to an output terminal of one of the plurality of delay cells, and the other end of the inverter 111 may be connected to the PMOS capacitor 112 and the NMOS capacitor 113. In some implementations, one end of the inverter 111 may be connected to an output terminal of one of the plurality of delay cells except for a first inverter of a first stage delay cell in the series of the plurality of delay cells. In some implementations, the other end of the inverter 111 may be connected to a substrate of the PMOS capacitor 112 and a substrate of the NMOS capacitor 113.

A Metal-Oxide-Semiconductor (MOS) capacitor may have a structure of a metal oxide semiconductor and may include a metal gate, an oxide insulating layer, and a substrate. The substrate may be a base on which a semiconductor element is manufactured, and may include a well region. The substrate may include a semiconductor material, for example, a group IV semiconductor, a group III-V compound semiconductor, or a group II-VI compound semiconductor. The MOS capacitor may control the amount of charge present on the surface of the substrate by controlling the voltage input to the gate.

In some implementations, a plurality of transistors included in the test subject, a PMOS transistor and an NMOS transistor included in the inverter, and a PMOS capacitor 112 and an NMOS capacitor 113 connected to the output terminal of the inverter may be manufactured through the same manufacturing process and may exhibit similar characteristics. The plurality of transistors included in the semiconductor die as the test subject and the transistors included in the inverter may be elements that add a source and a drain to a MOS capacitor.

The PMOS capacitor 112 and the NMOS capacitor 113 may have different capacitance depending on whether a channel is formed between the source and the drain or not. Whether a channel is formed may be determined by the relative potential difference between respective terminals of the PMOS capacitor 112 and the NMOS capacitor 113. The channel may be formed or not formed depending on the voltage level input to the gates of the PMOS capacitor 112 and the NMOS capacitor 113. If a channel is formed, it may have a larger capacitance than in a case in which a channel is not formed. For example, the capacitance acting as a load may be greater when a channel is formed than when it is not.

The voltage controller 120 may input a control voltage to the gate of the PMOS capacitor 112 and the gate of the NMOS capacitor 113. When a high control voltage is input to the gate of each of the PMOS capacitor 112 and the NMOS capacitor 113, the NMOS capacitor 113 may be charged, and when a low control voltage is input, the PMOS capacitor 112 may be charged.

The measurement circuit 130 may measure the delay time using the input voltage VIN input to the delay line DL and the output voltage VOUT output from the delay line. In some implementations, the input voltage VIN may be input to the delay line DL and the measurement circuit 130, respectively.

In the test circuit 100 according to some implementations, the voltage controller 120 may input a first control voltage to the gate of the PMOS capacitor 112 and the gate of the NMOS capacitor 113, and then input a second control voltage different from the first control voltage. In some implementations, the first control voltage may be lower than the second control voltage.

The first control voltage may be lower than the threshold voltage of the PMOS capacitor 112 and may form a channel in the PMOS capacitor 112. While the voltage controller 120 inputs the first control voltage to the gate of the PMOS capacitor 112, the capacitance of the PMOS capacitor 112 may be at its maximum. While the first control voltage is input to the gates of each of the PMOS capacitor 112 and the NMOS capacitor 113, the measurement circuit 130 may measure the first delay time.

The second control voltage is greater than the threshold voltage of the NMOS capacitor 113 and may form a channel in the NMOS capacitor 113. While the voltage controller 120 inputs the second control voltage to the gate of the NMOS capacitor 113, the capacitance of the NMOS capacitor 113 may be at its maximum. While the second control voltage is input to the respective gates of the PMOS capacitor 112 and the NMOS capacitor 113, the measurement circuit 130 may measure the second delay time.

The first delay time may be a value obtained by multiplying the sum of the delay time of the inverter 111 and the delay time of the PMOS capacitor 112 by the number of the plurality of delay cells 110. The second delay time may be a value obtained by multiplying the sum of the delay time of the inverter 111 and the delay time of the NMOS capacitor 113 by the number of the plurality of delay cells 110.

The delay time of the inverter 111 may be the falling delay time of the PMOS transistor and/or the rising delay time of the NMOS transistor. The delay time of the PMOS capacitor 112 may be the time for which the PMOS capacitor 112 acts as a load and is delayed. The delay time of the NMOS capacitor 113 may be the time for which the NMOS capacitor 113 acts as a load and is delayed.

The measurement circuit 130 may detect the rising delay time and the falling delay time of the inverter 111 by using the difference between the first delay time and the second delay time. In some implementations, if the first delay time is smaller than the second delay time, the measurement circuit 130 may determine that the rising delay time is longer than the falling delay time. If the first delay time is larger than the second delay time, the measurement circuit 130 may determine that the rising delay time is shorter than the falling delay time. If the first delay time and the second delay time are the same, the measurement circuit 130 may determine that the rising delay time and the falling delay time are the same.

Referring to FIG. 9, the test circuit 200 according to some implementations may share the same or equivalent technical features as the test circuit 100 described in FIG. 8 and, thus, descriptions overlapping with the configuration described in FIG. 8 will be briefly summarized or omitted.

The delay line DL may include a plurality of delay cells 210 that are connected to each other in series. Each of the plurality of delay cells 210 may include an inverter 211, a PMOS capacitor 212 and an NMOS capacitor 213. In the test circuit 200 according to some implementations, the input terminal and the output terminal of the delay line DL may be connected to each other. While the voltage controller 220 inputs the first control voltage to the respective gates of the PMOS capacitor 212 and the NMOS capacitor 213, the measurement circuit 230 may count the edge of the first output pulse signal. While the voltage controller 220 inputs the second control voltage to the respective gates of the PMOS capacitor 212 and the NMOS capacitor 213, the measurement circuit 230 may count the edge of the second output pulse signal. The measurement circuit 230 may detect the rising delay time and the falling delay time of the inverter 211 by comparing the edges of the first output pulse signal and the second output pulse signal.

If the number of edges of the first output pulse signal is greater than the number of edges of the second output pulse signal, the measurement circuit 230 may determine that the rising delay time may be longer than the falling delay time. If the number of edges of the first output pulse signal is less than the number of edges of the second output pulse signal, the measurement circuit 230 may determine that the rising delay time may be shorter than the falling delay time. If the number of edges of the first output signal and the number of edges of the second output signal are the same, the measurement circuit 230 may determine that the rising delay time and the falling delay time may be the same.

Referring to FIG. 4, when verifying the characteristics of the transistor using the absolute delay time, the average delay times of the PMOS transistor and the NMOS transistor may be similar in the case where the operating speed of the PMOS transistor is normal (TT), the operating speed of the PMOS transistor is fast and the operating speed of the NMOS transistor is slow (FS), and the operating speed of the PMOS transistor is slow and the operating speed of the NMOS transistor is fast (SF). Therefore, it may be difficult to clearly distinguish the characteristics of the transistor in the three cases.

A test circuit according to some implementations may connect a PMOS capacitor and an NMOS capacitor to the output terminal of an inverter included in a plurality of delay cells, and detect a rising delay time and a falling delay time by measuring a delay time, a pulse width, and/or an edge by a measurement circuit. In this way, the transistor characteristics of three cases (TT, SF and FS) may be distinguished, and the test results may be optimized according to the characteristics of the process. Therefore, the yield of the semiconductor manufacturing process may be improved, and the reliability of a semiconductor die and a semiconductor device manufactured by packaging the same may be improved.

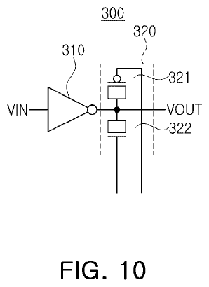

FIG. 10 is a diagram illustrating a delay cell according to some implementations.

Referring to FIG. 10, a delay cell 300 according to some implementations may include an inverter 310 and a capacitor circuit 320.

The inverter 310 may include an input terminal for receiving a pulse signal, and an output terminal for inverting the received pulse signal and outputting it. The capacitor circuit 320 may include a PMOS capacitor 321 and an NMOS capacitor 322 connected to the output terminal of the inverter 310.

While a first control voltage is input to the capacitor circuit 320, the inverter 310 may invert the pulse signal and output a first output pulse signal. While a second control voltage is input to the capacitor circuit 320, the inverter 310 may invert the pulse signal and output a second output pulse signal.

The width of the first output pulse signal may be the sum of the pulse width of the input pulse signal, the delay time of the inverter 310, and the delay time of the PMOS capacitor 321. The width of the second output pulse signal may be the sum of the pulse width of the input pulse signal, the delay time of the inverter 310, and the delay time of the NMOS capacitor 322.

The first pulse width of the first output pulse signal and the second pulse width of the second output pulse signal may be compared to detect the rising delay time and the falling delay time of the inverter 310. In some implementations, if the first pulse width is smaller than the second pulse width, the rising delay time may be determined to be longer than the falling delay time. If the rising delay time is determined to be longer than the falling delay time, the operating speed of the PMOS transistor may be relatively slow, and the operating speed of the NMOS transistor may be relatively fast.

If the first pulse width is larger than the second pulse width, the rising delay time may be determined to be shorter than the falling delay time. If the rising delay time is determined to be shorter than the falling delay time, the operating speed of the PMOS transistor may be relatively fast, and the operating speed of the NMOS transistor may be relatively slow. If the first pulse width and second pulse width are the same, it may be determined that the rising delay time and the falling delay time are the same.

The delay cell according to some implementations may measure the first pulse width and the second pulse width by inputting the first control voltage and the second control voltage to the PMOS capacitor and the NMOS capacitor. The delay cell may detect the rising delay time and the falling delay time by using the difference between the first pulse width and the second pulse width, and may determine the characteristics of the transistor based thereon. The characteristics of the transistor may be used to optimize the semiconductor die, and the yield of the semiconductor manufacturing process may be improved by using the same.

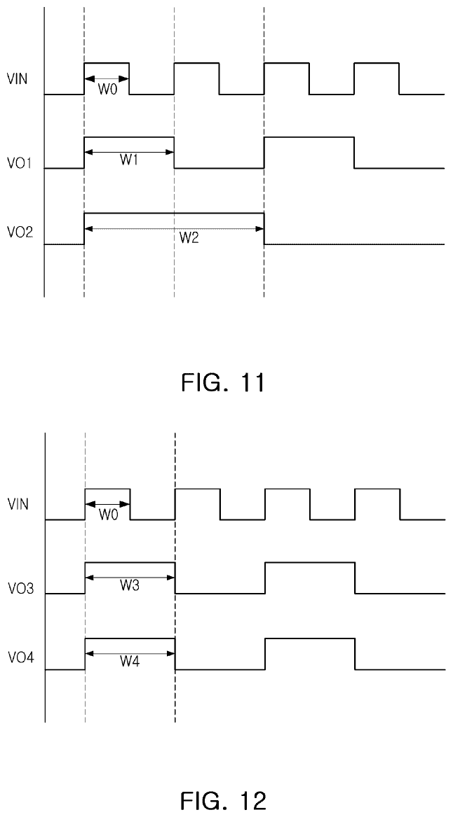

FIGS. 11 to 13 are diagrams illustrating the operation of a test circuit according to some implementations.

Referring to FIGS. 11 to 13, the test circuit according to some implementations may include a delay line, a voltage controller, and a measurement circuit. The delay line may include a plurality of delay cells, and each of the plurality of delay cells may include an inverter, a PMOS capacitor, and an NMOS capacitor. One end of the inverter may be connected to an output terminal of another inverter (in some implementations, except for a first inverter of a first stage delay cell in the series of the plurality of delay cells), and the other end of the inverter may be connected to a substrate of the PMOS capacitor and a substrate of the NMOS capacitor.

A pulse signal may be input to the delay line, and the voltage controller may input a control voltage to the gate of the PMOS capacitor and the gate of the NMOS capacitor. While the voltage controller inputs the control voltage to the gate of the PMOS capacitor and the gate of the NMOS capacitor, the measurement may measure the pulse width of the output pulse signal output from the delay line.

Referring to FIG. 11, an input pulse signal VIN may be input to the delay line according to some implementations, the voltage controller may input a first control voltage to the gate of the PMOS capacitor and the gate of the NMOS capacitor, and the measurement circuit may measure a first pulse width W1 of a first output pulse signal VO1. Afterwards, the voltage controller inputs a second control voltage to the gate of the PMOS capacitor and the gate of the NMOS capacitor, and the measurement circuit may measure the second pulse width W2 of the second output pulse signal VO2. While the first control voltage is input, the capacitance of the PMOS capacitor may be at its maximum, and while the second control voltage is input, the capacitance of the NMOS capacitor may be at its maximum.

The first pulse width W1 may be affected by the delay time of the PMOS capacitor, and the second pulse width W2 may be affected by the delay time of the NMOS capacitor. The first pulse width W1 may be calculated by multiplying the sum of the pulse width W0 of the input pulse signal, the delay time of the inverter, and the delay time of the PMOS capacitor by the number of the plurality of delay cells. The second pulse width W2 may be calculated by multiplying the sum of the pulse width W1 of the input pulse signal, the delay time of the inverter, and the delay time of the NMOS capacitor by the number of the plurality of delay cells.

The measurement circuit may detect the rising delay time and the falling delay time of the inverter by comparing the first pulse width W1 and the second pulse width W2. If the first pulse width W1 is smaller than the second pulse width W2, the measurement circuit may determine that the rising delay time is longer than the falling delay time.

The characteristics of the PMOS transistor may be dominant in the rising delay time, and the characteristics of the NMOS transistor may be dominant in the falling delay time. If the characteristics of the PMOS transistor are relatively poor and the characteristics of the NMOS transistor are relatively good, the rising delay time may be longer than the falling delay time. Therefore, the measurement circuit may determine that the operating speed of the PMOS transistor included in the semiconductor die under test is relatively slow and the operating speed of the NMOS transistor is relatively fast by using the difference between the first pulse width W1 and the second pulse width W2.

Referring to FIG. 12, an input pulse signal VIN may be input to a delay line according to some implementations, the voltage controller may input a first control voltage to the gate of the PMOS capacitor and the gate of the NMOS capacitor, and the measurement circuit may measure a third pulse width W3 of a third output pulse signal VO3. Afterwards, the voltage controller may input a second control voltage to the gate of the PMOS capacitor and the gate of the NMOS capacitor, and the measurement circuit may measure a fourth pulse width W4 of a fourth output pulse signal VO4.

The measurement circuit may detect a rising delay time and a falling delay time of an inverter by comparing the third pulse width W3 and the fourth pulse width W4. If the third pulse width W3 and the fourth pulse width W4 are the same, the measurement circuit may determine that the rising delay time and the falling delay time are the same.

If the characteristics of the PMOS transistor and the characteristics of the NMOS transistor are similar, the rising delay time and the falling delay time may be the same. For example, if the operating speed of the PMOS transistor is relatively fast and the operating speed of the NMOS transistor is also relatively fast, the rising delay time and the falling delay time may be the same. Therefore, the measurement circuit may determine whether the characteristics of the PMOS transistor and the characteristics of the NMOS transistor are similar by using the third pulse width W3 and the fourth pulse width W4.

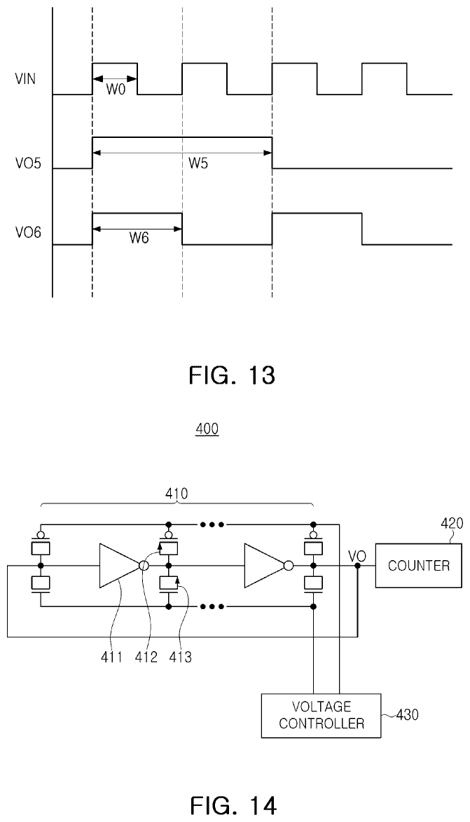

Referring to FIG. 13, an input pulse signal VIN may be input to the delay line, the voltage controller may input a first control voltage to the gate of the PMOS capacitor and the gate of the NMOS capacitor, and the measurement circuit may measure a fifth pulse width W5 of a fifth output pulse signal VO5. Afterwards, the voltage controller may input a second control voltage to the gate of the PMOS capacitor and the gate of the NMOS capacitor, and the measurement circuit may measure a sixth pulse width W6 of a sixth output pulse signal VO6.

The measurement circuit may detect the rising delay time and the falling delay time of the inverter by comparing the fifth pulse width W5 and the sixth pulse width W6. If the fifth pulse width W5 is greater than the sixth pulse width W6, the measurement circuit may determine that the rising delay time is shorter than the falling delay time.

If the characteristics of the PMOS transistor are relatively good and the characteristics of the NMOS transistor are relatively bad, the rising delay time may be shorter than the falling delay time. Therefore, the measurement circuit may determine that the operating speed of the PMOS transistor included in the semiconductor die to be tested is relatively fast and the operating speed of the NMOS transistor is relatively slow by using the difference between the fifth pulse width W5 and the sixth pulse width W6.

A test circuit according to some implementations may include a PMOS capacitor and an NMOS capacitor, and may input a first control voltage to respective gates of the PMOS capacitor and the NMOS capacitor and measure a first pulse width, and then input a second control voltage and measure a second pulse width. By comparing the first pulse width and the second pulse width, the rising delay speed and the falling delay speed may be detected, and the characteristics of the transistor may be determined. The three cases of transistor characteristics (TT, FS, SF) that are difficult to distinguish using the absolute delay speed may be clearly distinguished, and the reliability of the semiconductor die and the semiconductor device manufactured by packaging the same may be improved by performing optimization according to the characteristics of the transistor.

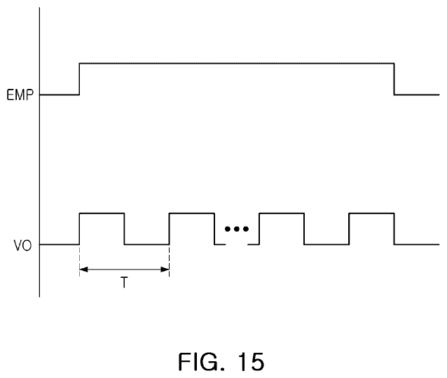

FIG. 14 and FIG. 15 are diagrams illustrating the operation of a test circuit according to some implementations.

First, referring to FIG. 14, a test circuit 400 according to some implementations may share the same or corresponding technical features as the test circuit 200 described in FIG. 9, so descriptions that overlap with the configuration described in FIG. 9 will be briefly summarized or omitted.

A test circuit 400 according to some implementations may include a delay line 410, a counter 420, and a voltage controller 430.

The delay line 410 may include a plurality of delay cells, and each of the plurality of delay cells may include an inverter 411, a PMOS capacitor 412, and an NMOS capacitor 413. In some implementations, the plurality of delay cells are odd in number, and may operate as a ring oscillator by a feedback loop in which the input terminal of the first delay cell and the output terminal of the Nth delay cell are connected to each other. N may be an odd number greater than or equal to 1.

The counter 420 may include a plurality of shift registers and may count pulses passing through the delay line 410. The counter 420 may include a plurality of shift registers connected in series and may be, for example, a 10-stage binary counter. The counter 420 may count pulses of an output pulse signal VO output from the delay line 410 and detect a rising delay time and a falling delay time of the inverter 411. In some implementations, the output pulse signal VO output from the delay line 410 may be input as a clock signal for the register.

Referring to FIGS. 14 and 15, when the External Measure Pulse (EMP) is high, the counter 420 may count the number of pulses or the number of edges of the output pulse signal VO output from the test circuit 400. In some implementations, the test circuit 400 may measure the delay time T by using the number of pulses or the number of edges of the output pulse signal VO through the counter 420. The delay time T may be the time from when a signal is input to the first delay cell to when a signal is output from the Nth delay cell in the test circuit 400 including N delay cells (N may be an odd number greater than or equal to 1).

According to some implementations, the test circuit 400 may include the PMOS capacitor 412 and the NMOS capacitor 413 to test the characteristics of transistors, and may determine the delay characteristics of an output pulse signal with respect to an input pulse signal while changing the control voltage input to respective gates of the PMOS capacitor 412 and the NMOS capacitor 413. For example, the counter 420 may measure the number of pulses or the number of edges of an output pulse signal. For example, if the number of pulses of a first output pulse signal is greater than the number of second output pulse signals, the test circuit 400 may determine that the rising delay time is longer than the falling delay time. In this way, the rising delay time and the falling delay time may be detected by comparing the number of pulses or the number of edges measured while changing the control voltage input to respective gates of the PMOS capacitor 412 and the NMOS capacitor 413. Based on these test results, a semiconductor die, or the like, which is a test target, may be optimized, and thus the yield of a semiconductor manufacturing process may be improved.

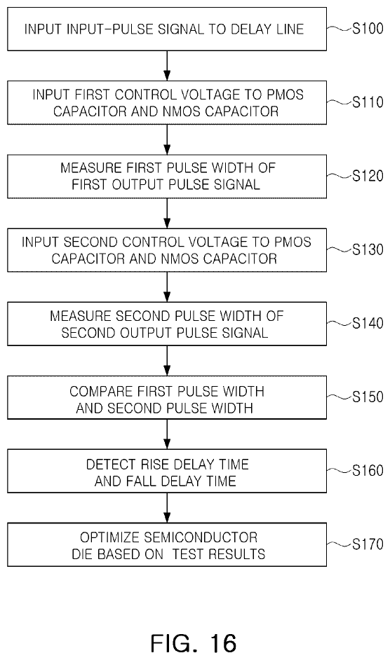

FIG. 16 is a flow chart illustrating the operation of a test circuit according to some implementations.

In some implementations, the test circuit may include a delay line, a voltage controller, a measurement circuit, and the like. The delay line may include a plurality of delay cells, and the plurality of delay cells may include a PMOS capacitor and an NMOS capacitor connected to an output terminal of an inverter. The voltage controller may input a control voltage to the gate of the PMOS capacitor and the gate of the NMOS capacitor. The measurement circuit may measure a delay time, pulse width, or the like of a pulse signal output from the delay line.

In some implementations, an input pulse signal may be input to the delay line (S100). The delay line may include a plurality of delay cells connected in series to each other, and an input pulse signal may be input to the first delay cell. In some implementations, a PMOS capacitor and an NMOS capacitor may also be connected to the input terminal of an inverter included in the first delay cell.

The voltage controller may input a first control voltage to the PMOS capacitor and the NMOS capacitor (S110). The first control voltage is a voltage lower than the threshold voltage of the PMOS capacitor, which may form a channel between the source and drain of the PMOS capacitor and charge the PMOS capacitor to the maximum. The first control voltage may not form a channel between the source and drain of the NMOS capacitor.

The measurement circuit may measure the first pulse width of the first output pulse signal (S120). While the voltage controller inputs the first control voltage, the input pulse signal may be output from a delay line to which multiple delay cells are connected. The first pulse width of the first output pulse signal may be a value obtained by multiplying the sum of the pulse width of the input pulse signal, the delay time of the inverter, and the delay time of the PMOS capacitor by the number of multiple delay cells.

After the measurement circuit measures the first pulse width, the voltage controller may input the second control voltage to the PMOS capacitor and the NMOS capacitor (S130). The second control voltage is a voltage higher than the threshold voltage of the NMOS capacitor, may form a channel between the source and drain of the NMOS capacitor, and may charge the NMOS capacitor to the maximum. The second control voltage may not form a channel between the source and drain of the PMOS capacitor.

The measurement circuit may measure the second pulse width of the second output pulse signal (S140). While the voltage controller inputs the second control voltage, a second output pulse signal may be output from the delay line. The second pulse width may be a value obtained by multiplying the sum of the pulse width of the input pulse signal, the delay time of the inverter, and the delay time of the NMOS capacitor by the number of multiple delay cells.

The measurement circuit may compare the first pulse width and the second pulse width (S150). Depending on the characteristics of the PMOS transistor and the NMOS transistor in the inverter, the first pulse width and the second pulse width may be the same, the first pulse width may be greater than the second pulse width, or the first pulse width may be smaller than the second pulse width. The measurement circuit may compare the first pulse width and the second pulse width and determine the difference.

The measurement circuit may detect the rising delay time and the falling delay time of the inverter (S160). The measurement circuit may detect the falling delay time of the PMOS transistor and the rising delay time of the NMOS transistor by using the difference between the first pulse width and the second pulse width. The characteristics of the PMOS transistor may be dominant in the rising delay time, and the characteristics of the NMOS transistor may be dominant in the falling delay time. For example, if the manufacturing process of the PMOS transistor is well performed and the operating speed of the PMOS transistor is relatively fast, the rising delay time may be relatively short. If the rising delay time is short, the pulse width may be relatively large and the number of edges may be relatively small.

For example, if the first pulse width is smaller than the second pulse width, the measurement circuit may determine that the rising delay time is longer than the falling delay time and, based on this determination, may determine that the operating speed of the PMOS transistor is relatively slow and the operating speed of the NMOS transistor is relatively fast.

Thereafter, the semiconductor die may be optimized based on the test results (S170). In some implementations, the step of applying the test circuit and the step of optimizing may be performed at the wafer level and/or the package level, respectively. For example, the duty cycle of the DQ output signal of the semiconductor die may be optimized based on the test results to improve the performance of the semiconductor die, or the duty cycle of the clock signal may be optimized to improve the stability and accuracy of the signal. Through optimization, the reliability and efficiency of the semiconductor die may be improved, and potential problems may be prevented in advance.

According to some implementations, a test circuit may determine the delay characteristics of an output pulse signal with respect to an input pulse signal by including a PMOS capacitor and an NMOS capacitor, and changing the control voltage on the respective gates of the PMOS capacitor and the NMOS capacitor. In this way, the rising delay time and the falling delay time may be detected, and the characteristics of the transistor may be determined based thereon. After the test stage, the semiconductor die may be optimized according to the characteristics of the process. Therefore, the yield of the semiconductor manufacturing process may be improved, and the reliability of the semiconductor die and the semiconductor device manufactured by packaging the same may be improved.

As set forth above, according to some implementations, a PMOS capacitor and an NMOS capacitor may be included in a test circuit for testing characteristics of transistors, a voltage controller may input a first control voltage and a second control voltage to the gate of a PMOS capacitor and the gate of an NMOS capacitor, and a measurement circuit may measure a first pulse width when the first control voltage is input, and may measure a second pulse width when the second control voltage is input. The measurement circuit may detect a rising delay time and a falling delay time of the transistor by using a difference between the first pulse width and the second pulse width, and may identify characteristics related to the operation speed of the transistor. Therefore, by identifying an operation speed of the transistor and optimizing a test subject according to the characteristics of the process, reliability of a semiconductor die and a semiconductor device manufactured by packaging the same may be improved.

It will be appreciated that some implementations may utilize one or more specialized processors (or “processing devices”) such as microprocessors, digital signal processors, customized processors, and field programmable gate arrays (FPGAs) along with unique stored program instructions (including software and/or firmware) that control the one or more processors to implement, in conjunction with certain non-processor circuits, some, most, or all of the functions of the method and/or apparatus described herein. Alternatively, some or all of these functions could be implemented using a state machine without stored program instructions, or through one or more application specific integrated circuits (ASICs), where each function or some combinations of certain of the functions are implemented as custom logic. A hybrid approach combining these techniques may also be employed.

Moreover, an implementation may take the form of a computer-readable storage medium having computer readable code stored thereon for programming a computer (e.g., including a processor) to perform a method as described and/or claimed herein. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory), and a Flash memory. Furthermore, one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While some implementations have been illustrated and described above, it will be apparent to those skilled in the art that modifications and variations could be made without departing from the scope of the present disclosure.

What is claimed is:

1. A test circuit comprising:
a delay line including a plurality of delay cells connected to each other in series, each of the plurality of delay cells including an inverter, a PMOS capacitor, and an NMOS capacitor, a first end of the inverter being connected to the PMOS capacitor and the NMOS capacitor;
a voltage controller configured to:
input a first control voltage to a gate of the PMOS capacitor and a gate of the NMOS capacitor at a first time, and
input a second control voltage to the gate of the PMOS capacitor and the gate of the NMOS capacitor at a second time after the first time, the second control voltage being different from the first control voltage; and
a measurement circuit configured to measure a delay time of the inverter using an input voltage input to the delay line and an output voltage output from the delay line,
wherein the measurement circuit is configured to:
measure a first delay time based on the first control voltage being input to the gate of the PMOS capacitor and the gate of the NMOS capacitor,
measure a second delay time based on the second control voltage being input to the gate of the PMOS capacitor and the gate of the NMOS capacitor, and
detect a rising delay time and a falling delay time of the inverter by using a difference between the first delay time and the second delay time.

2. The test circuit of claim 1, wherein the first delay time is a value based on multiplying a sum of the delay time of the inverter and a delay time of the PMOS capacitor by a number of the plurality of delay cells, and
wherein the second delay time is a value based on multiplying a sum of the delay time of the inverter and a delay time of the NMOS capacitor by the number of the plurality of delay cells.

3. The test circuit of claim 1, wherein the PMOS capacitor is configured to have a maximum capacitance while the voltage controller inputs the first control voltage to the gate of the PMOS capacitor, and
wherein the NMOS capacitor is configured to have a maximum capacitance while the voltage controller inputs the second control voltage to the gate of the NMOS capacitor.

4. The test circuit of claim 1, wherein the first control voltage is lower than the second control voltage.

5. The test circuit of claim 1, wherein the first control voltage is lower than a threshold voltage of the PMOS capacitor, and the second control voltage is higher than a threshold voltage of the NMOS capacitor.

6. The test circuit of claim 1, wherein the measurement circuit is configured to determine that the rising delay time is longer than the falling delay time based on the first delay time being shorter than the second delay time.

7. The test circuit of claim 1, wherein the measurement circuit is configured to determine that the rising delay time is shorter than the falling delay time based on the first delay time being longer than the second delay time.

8. The test circuit of claim 1, wherein the measurement circuit is configured to determine that the rising delay time and the falling delay time are a same as each other based on the first delay time and the second delay time being a same with each other.

9. The test circuit of claim 1, wherein the input voltage is input to both of the delay line and the measurement circuit.

10. The test circuit of claim 1, wherein an input terminal and an output terminal of the delay line are separated from each other.

11. The test circuit of claim 1, wherein the first end of the inverter is connected to a substrate of the PMOS capacitor and a substrate of the NMOS capacitor.

12. A delay cell comprising:
an inverter configured to invert an input pulse signal and including:
an input terminal configured to receive the input pulse signal, and
an output terminal configured to output the inverted input pulse signal; and
a capacitor circuit including a PMOS capacitor and an NMOS capacitor connected to the output terminal of the inverter,
wherein the inverter is configured to output a first pulse width of a first output pulse signal based on a first control voltage being input to the capacitor circuit, and configured to output a second pulse width of a second output pulse signal based on a second control voltage different from the first control voltage being input to the capacitor circuit, and
wherein the first pulse width and the second pulse width are configured to be compared with each other to detect a rising delay time and a falling delay time of the inverter.

13. The delay cell of claim 12, wherein the rising delay time is determined to be longer than the falling delay time based on the first pulse width being smaller than the second pulse width.

14. The delay cell of claim 12, wherein the rising delay time and the falling delay time are determined to be a same as each other based on the first pulse width and the second pulse width being a same with each other.

15. The delay cell of claim 12, wherein the rising delay time is determined to be shorter than the falling delay time based on the first pulse width being larger than the second pulse width.

16. The delay cell of claim 12, wherein the first pulse width is a sum of a pulse width of the input pulse signal, a delay time of the inverter, and a delay time of the PMOS capacitor, and
wherein the second pulse width is a sum of the pulse width of the input pulse signal, the delay time of the inverter, and a delay time of the NMOS capacitor.

17. A test circuit comprising:
a delay line including a plurality of delay cells connected to each other in series, each of the plurality of delay cells including an inverter, a PMOS capacitor, and an NMOS capacitor, wherein the PMOS capacitor and the NMOS capacitor are connected to an output terminal of the inverter; and
a counter including a plurality of shift registers and configured to count a number of pulses of output pulse signals output from the delay line,
wherein a number of the plurality of delay cells is N, wherein N is an odd number greater than or equal to 1, and wherein an input terminal of a first delay cell and an output terminal of an Nth delay cell are connected to operate as a feedback loop, and
wherein based on a control voltage being input to a gate of the PMOS capacitor and a gate of the NMOS capacitor, the counter is configured to receive the output pulse signals as clock signals and count the number of pulses of the output pulse signals to detect a rising delay time and a falling delay time of the inverter.

18. The test circuit of claim 17, wherein the PMOS capacitor and the NMOS capacitor are connected to an input terminal of the inverter included in the first delay cell.

19. The test circuit of claim 17, wherein the test circuit is configured to determine that the rising delay time is longer than the falling delay time based on a number of pulses of a first output pulse signal output from the delay line based on a first control voltage being input to a gate of each of the PMOS capacitor and the NMOS capacitor being greater than a number of pulses of a second output pulse signal output from the delay line based on a second control voltage different from the first control voltage being input to the gate of each of the PMOS capacitor and the NMOS capacitor.

20. The test circuit of claim 17, wherein the test circuit is configured to determine that the rising delay time is shorter than the falling delay time based on a number of pulses of a first output pulse signal output from the delay line based on a first control voltage being input to a gate of each of the PMOS capacitor and the NMOS capacitor being less than a number of pulses of a second output pulse signal output from the delay line based on a second control voltage different from the first control voltage being input to the gate of each of the PMOS capacitor and the NMOS capacitor.
